(19) United States
(12) Patent Application Publication
(10) Pub. No.: US 2025/0175141 A1
(43) Pub. Date: May 29, 2025

(54) ACOUSTIC WAVE DEVICE

(71) Applicant: TAIYO YUDEN CO., LTD., Tokyo (JP)

(72) Inventor: Mayu TSUKADA, Tokyo (JP)

(73) Assignee: TAIYO YUDEN CO., LTD., Tokyo (JP)

(21) Appl. No.: 18/926,715

(22) Filed: Oct. 25, 2024

(30) Foreign Application Priority Data
Nov. 29, 2023 (JP) 2023-202166

(51) Int. Cl. H03H 9/02; H03H 9/145; H03H 9/25

(52) U.S. Cl. CPC H03H 9/02858; H03H 9/02574; H03H 9/02992; H03H 9/145; H03H 9/25

(57) ABSTRACT

An acoustic wave device includes a pair of comb-shaped electrodes provided on a piezoelectric substrate, each of the pair of comb-shaped electrodes including electrode fingers and metal portions that are provided between electrode fingers adjacent to each other, the metal portions having a shorter length than the electrode fingers, the electrode fingers of one comb-shaped electrode and the electrode fingers of the other comb-shaped electrode being alternately arranged at least in a part, an acoustic velocity of an acoustic wave propagating through a region where the metal portions are located being higher than an acoustic velocity of an acoustic wave propagating through a central region of an overlap region where the electrode fingers of the one comb-shaped electrode and the electrode fingers of the other comb-shaped electrode overlap, and being equal to or less than 1.10 times the acoustic velocity of the acoustic wave propagating through the central region.

### CROSS-REFERENCE TO RELATED APPLICATION

This application is based upon and claims the benefit of priority of the prior Japanese Patent Application No. 2023-202166, filed on Nov. 29, 2023, the entire contents of which are incorporated herein by reference.

### FIELD

A certain aspect of the present disclosure relates to an acoustic wave device.

### BACKGROUND

Acoustic wave devices are used in high-frequency communication systems typified by mobile phones. As an acoustic wave device, an acoustic wave device including a pair of comb-shaped electrodes each including a plurality of electrode fingers, a plurality of dummy electrode fingers, and a bus bar to which the electrode fingers and the dummy electrode fingers are coupled is known as disclosed in, for example, Japanese Patent Application Laid-Open Nos. 2007-68107 and 2003-218665 and Japanese Translation of PCT International Publication No. 2013-518455 (Patent Documents 1 to 3). In addition, as a method of reducing spurious emissions without deteriorating the Q factor, an acoustic wave device using a piston mode is known as disclosed in, for example, Japanese Patent Application Laid-Open Nos. 2022-11770 and 2022-126852 (Patent Documents 4 and 5).

### SUMMARY

The piston mode is used to reduce spurious emissions. However, there is still room for improvement in terms of reduction of spurious emissions.

An object of the present disclosure is to reduce spurious emissions.

In one aspect of the present disclosure, there is provided an acoustic wave device including: a piezoelectric substrate; and a pair of comb-shaped electrodes provided on the piezoelectric substrate, each of the pair of comb-shaped electrodes including a plurality of electrode fingers and a plurality of metal portions, the plurality of metal portions being provided between electrode fingers adjacent to each other in a short direction of the plurality of electrode fingers, the plurality of metal portions having a shorter length in a long direction than the plurality of electrode fingers, the plurality of electrode fingers of one of the pair of comb-shaped electrodes and the plurality of electrode fingers of the other of the pair of comb-shaped electrodes being alternately arranged at least in a part, an acoustic velocity of an acoustic wave propagating through a region where the plurality of metal portions are located being higher than an acoustic velocity of an acoustic wave propagating through a central region of an overlap region where the plurality of electrode fingers of the one of the pair of comb-shaped electrodes and the plurality of electrode fingers of the other of the pair of comb-shaped electrodes overlap, and being equal to or less than 1.10 times the acoustic velocity of the acoustic wave propagating through the central region.

In another aspect of the present disclosure, there is provided an acoustic wave device including: a piezoelectric substrate; and a pair of comb-shaped electrodes provided on the piezoelectric substrate, each of the pair of comb-shaped electrodes including a plurality of electrode fingers and a plurality of metal portions, two or more of the plurality of metal portions being provided between adjacent electrode fingers in a short direction of the plurality of electrode fingers, the plurality of metal portions having a smaller width in the short direction than the plurality of electrode fingers, the plurality of electrode fingers of one of the pair of comb-shaped electrode fingers and the plurality of electrode fingers of the other of the pair of comb-shaped electrode fingers being alternately arranged at least in a part.

In another aspect of the present disclosure, there is provided an acoustic wave device including: a piezoelectric substrate; and a pair of comb-shaped electrodes provided on the piezoelectric substrate, each of the pair of comb-shaped electrodes including a plurality of electrode fingers and a plurality of metal portions, the plurality of metal portions being provided between adjacent electrode fingers of the plurality of electrode fingers in a short direction of the plurality of electrode fingers, the plurality of metal portions containing a material having a higher acoustic velocity of an acoustic wave than the plurality of electrode fingers as a main component, the plurality of electrode fingers of one of the pair of comb-shaped electrodes and the plurality of electrode fingers of the other of the pair of comb-shaped electrodes being alternately arranged at least in a part.

### BRIEF DESCRIPTION OF THE DRAWINGS

FIG. 1A is a plan view of an acoustic wave device in accordance with a first embodiment, and FIG. 1B is a cross-sectional view taken along line A-A in FIG. 1A;

FIG. 2A is a plan view of an acoustic wave device in accordance with a comparative example, and FIG. 2B is a cross-sectional view taken along line A-A in FIG. 2A;

FIG. 3A illustrates the acoustic velocity of an acoustic wave in the comparative example, and FIG. 3B illustrates the acoustic velocity of an acoustic wave in the first embodiment;

FIG. 4A is a plan view of models A and B used in Simulation 1, FIG. 4B is a cross-sectional view taken along line A-A in FIG. 4A, FIG. 4C is a plan view of a model C used in Simulation 1, and FIG. 4D is a cross-sectional views taken along line A-A in FIG. 4C;

FIG. 5 is a graph illustrating the absolute value |Y| of admittance with respect to frequency in Simulation 1;

FIG. 6A and FIG. 6B are graphs (No. 1) illustrating the real part Real(Y) of admittance with respect to frequency in Simulation 2;

FIG. 7A and FIG. 7B are graphs (part 2) illustrating the real part Real (Y) of admittance with respect to frequency in Simulation 2;

FIG. 8A is a plan view of an acoustic wave device in accordance with a first variation of the first embodiment, and FIG. 8B is a cross-sectional view taken along line A-A in FIG. 8A;

FIG. 9 presents experimental results of the real part Real(Y) of admittance with respect to frequency in the first embodiment and the first variation of the first embodiment;

FIG. 10A and FIG. 10B are experimental results of the real part Real(Y) of admittance with respect to frequency when the multilayer structure of a substrate is changed in the first embodiment and the first variation of the first embodiment;

FIG. 11A is a plan view of an acoustic wave device in accordance with a second variation of the first embodiment, and FIG. 11B is a cross-sectional view taken along line A-A in FIG. 11A;

FIG. 12A is a plan view of an acoustic wave device in accordance with a third variation of the first embodiment, and FIG. 12B is a cross-sectional view taken along line A-A in FIG. 12A;

FIG. 13A is a plan view of a case where three dummy electrode fingers are provided between adjacent electrode fingers in the first embodiment, and FIG. 13B is a cross-sectional view taken along line A-A in FIG. 13A; and

FIG. 14A is a circuit diagram of a filter in accordance with a second embodiment, and FIG. 14B is a circuit diagram of a duplexer in accordance with a variation of the second embodiment.

### DETAILED DESCRIPTION

Hereinafter, embodiments of the present disclosure will be described with reference to the drawings.

### First Embodiment

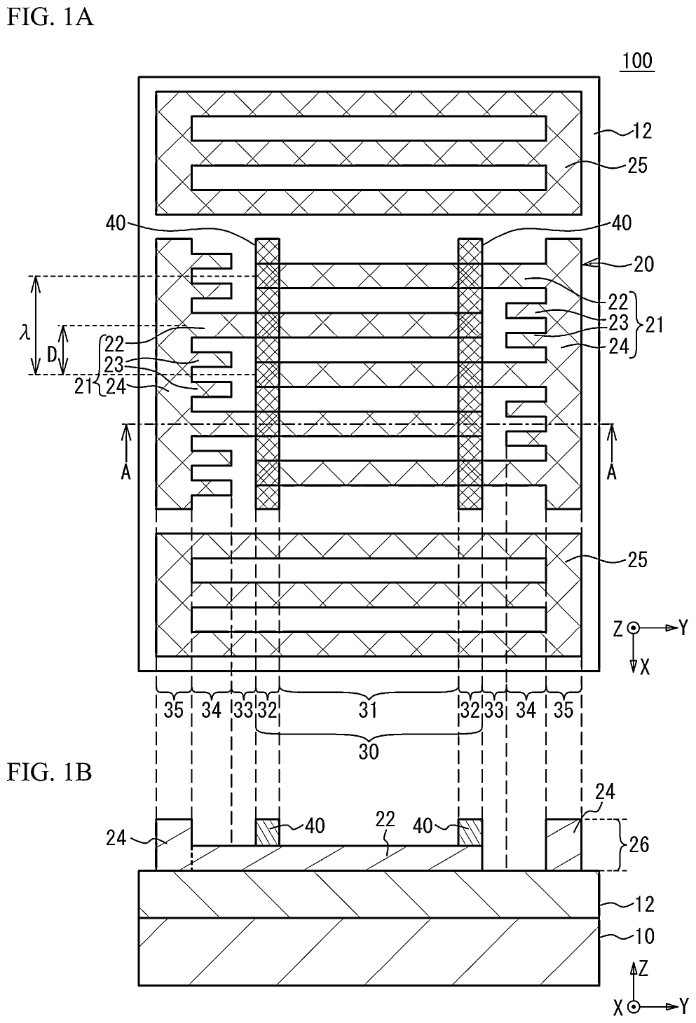

FIG. 1A is a plan view of an acoustic wave device 100 in accordance with a first embodiment, and FIG. 1B is a cross-sectional view taken along line A-A in FIG. 1A. The short direction of an electrode finger 22 is defined as an X direction, the long direction of the electrode finger 22 is defined as a Y direction, and the thickness direction of a piezoelectric substrate 12 is defined as a Z direction. The short direction of the electrode finger 22 is also the arrangement direction of the electrode fingers 22. The X direction, the Y direction, and the Z direction do not necessarily correspond to the X-axis orientation and the Y-axis orientation of the crystal orientations of the piezoelectric substrate 12. When the piezoelectric substrate 12 is a rotated Y-cut X-propagation piezoelectric substrate, the X direction is the X-axis orientation of the crystal orientations.

As illustrated in FIG. 1A and FIG. 1B, the piezoelectric substrate 12 is bonded on a support substrate 10. The support substrate 10 is, for example, a sapphire substrate, an alumina substrate, a spinel substrate, a quartz substrate, a crystal substrate, a silicon carbide substrate, or a silicon substrate. The piezoelectric substrate 12 is, for example, a monocrystalline lithium tantalate substrate or a monocrystalline lithium niobate substrate, and is, for example, a rotated Y-cut X-propagation lithium tantalate substrate or a rotated Y-cut X-propagation lithium niobate substrate. The piezoelectric substrate 12 may be, for example, a 30° to 50° Y-cut X-propagation lithium tantalate substrate. An insulating layer made of silicon oxide, aluminum oxide, and/or aluminum nitride may be provided between the support substrate 10 and the piezoelectric substrate 12. As described above, the piezoelectric substrate 12 is directly or indirectly bonded to the support substrate 10.

An interdigital transducer (IDT) 20 and reflectors 25 are provided on the piezoelectric substrate 12. The IDT 20 includes a pair of comb-shaped electrodes 21. The comb-shaped electrode 21 includes a plurality of the electrode fingers 22, a plurality of dummy electrode fingers 23, a bus bar 24 to which the electrode fingers 22 and the dummy electrode fingers 23 are connected. Two or more of the dummy electrode fingers are provided between the electrode fingers 22 adjacent to each other in the X direction. Here, a case where two dummy electrode fingers 23 are provided between the electrode fingers 22 adjacent to each other in the X direction is illustrated as an example. The width of the electrode finger 22 and the width of the dummy electrode finger 23 in the X direction are constant from one end connected to the bus bar 24 to the other end on the opposite side. The width of the dummy electrode finger 23 in the X direction is smaller than the width of the electrode finger 22 in the X direction. The thickness of the electrode finger 22 is the same as the thickness of the dummy electrode finger 23. The same thickness means that a difference of about a manufacturing error is acceptable, and for example, a ratio of two thicknesses of 0.95 or more and 1.05 or less is acceptable. The dummy electrode finger 23 is an example of a metal portion in the claims.

The IDT 20 and the reflectors 25 are formed of a metal film 26 on the piezoelectric substrate 12. The metal film 26 is a film containing, for example, aluminum, copper, molybdenum, iridium, platinum, rhenium, rhodium, ruthenium, tantalum, or tungsten as a main component. An adhesion film made of titanium, chromium, or the like may be provided between the piezoelectric substrate 12 and the electrode fingers 22, between the piezoelectric substrate 12 and the dummy electrode fingers 23, and between the piezoelectric substrate 12 and the bus bars 24. The adhesion film is thinner than the electrode fingers 22, the dummy electrode fingers 23, and the bus bars 24.

The region where the electrode fingers 22 of one of the pair of comb-shaped electrodes 21 and the electrode fingers 22 of the other of the pair of comb-shaped electrodes 21 overlap is an overlap region 30. The length of the overlap region 30 in the Y direction is an aperture length. The pair of comb-shaped electrodes 21 face each other so that the electrode fingers 22 of one of the pair of comb-shaped electrodes 21 and the electrode fingers 22 of the other of the pair of comb-shaped electrodes 21 are alternately arranged in the X direction at least in a part of the overlap region 30. The acoustic wave (surface acoustic wave) of the main mode excited by the electrode fingers 22 in the overlap region 30 propagates mainly in the X direction. The pitch of the electrode fingers 22 of one comb-shaped electrode 21 is substantially equal to the wavelength λ of the surface acoustic wave. The wavelength k is approximately twice the pitch D of the electrode fingers 22. The reflectors 25 reflect the surface acoustic wave excited by the electrode fingers 22 of the IDT 20. Thus, the surface acoustic wave is confined in the overlap region 30 of the IDT 20.

The overlap region 30 includes edge regions 32, which are regions located at respective edges in the Y direction, and a central region 31, which is a region located further in than the edge regions 32 in the Y direction. The edge regions 32 can also be said to be regions of the overlap region 30 where the tip portions of the electrode fingers 22 are located. A region located between the tip of the electrode finger 22 of one comb-shaped electrode 21 and the tip of the dummy electrode finger 23 of the other comb-shaped electrode 21 is a gap region 33. The region where the dummy electrode fingers 23 are located is a dummy region 34. The region where the bus bar 24 is located is a bus bar region 35. The dummy region 34 is an example of a region where a plurality of metal portions are located in the claims.

An additional film 40 is provided on the piezoelectric substrate 12 in the edge region 32. The additional film 40 covers the electrode fingers 22 located in each of the edge regions 32. The additional film 40 is also provided in a part of the edge region 32 where the electrode fingers 22 are not provided. No additional film 40 is provided in the central region 31, the gap region 33, the dummy region 34, and the bus bar region 35.

The additional film 40 is an insulating film containing, for example, silicon oxide, tantalum oxide, or niobium oxide as a main component, but may be a film containing another material as a main component as long as the acoustic velocity of the acoustic wave propagating through the edge region 32 can be adjusted.

Here, when a film contains an element as its main component, the film may contain intentional or unintentional impurities other than the main component. When a certain element is a main component in a certain film, the concentration of the certain element is, for example, 50 at % or greater, or for example, 80 at % or greater. In the case that two elements are the main components as in the case of silicon oxide or the like, the total of the concentration of silicon and the concentration of oxygen is, for example, 50 at % or greater, for example, 80 at % or greater, and the concentration of silicon and the concentration of oxygen are each, for example, 10 at % or greater.

### Manufacturing Method

A method of manufacturing the acoustic wave device 100 according to the first embodiment will be described. First, the piezoelectric substrate 12 is bonded onto the support substrate 10 using, for example, a surface activation method. Thereafter, the piezoelectric substrate 12 is polished to a desired thickness using, for example, a chemical mechanical polishing (CMP) method. Then, the metal film 26 is formed on the piezoelectric substrate 12 and then patterned into a desired shape. This forms the IDT 20 including the pair of comb-shaped electrodes 21 each including the electrode fingers 22, the dummy electrode fingers 23, and the bus bar 24, and forms the reflectors 25 on the piezoelectric substrate 12. The metal film 26 is formed by, for example, sputtering, vacuum evaporation, or chemical vapor deposition (CVD). The metal film 26 is patterned by, for example, photolithography and etching.

Then, the additional film 40 is formed so as to cover the electrode fingers 22 in each of the edge regions 32. The additional film 40 is formed by, for example, forming a mask layer having an opening in the edge region 32 on the piezoelectric substrate 12, forming the additional film 40 using the mask layer as a mask, and then removing the mask layer. The mask layer is formed of, for example, a photoresist. The additional film 40 is formed by, for example, sputtering, vacuum evaporation, or CVD. Through the above process, the acoustic wave device 100 in accordance with the first embodiment is formed.

### Comparative Example

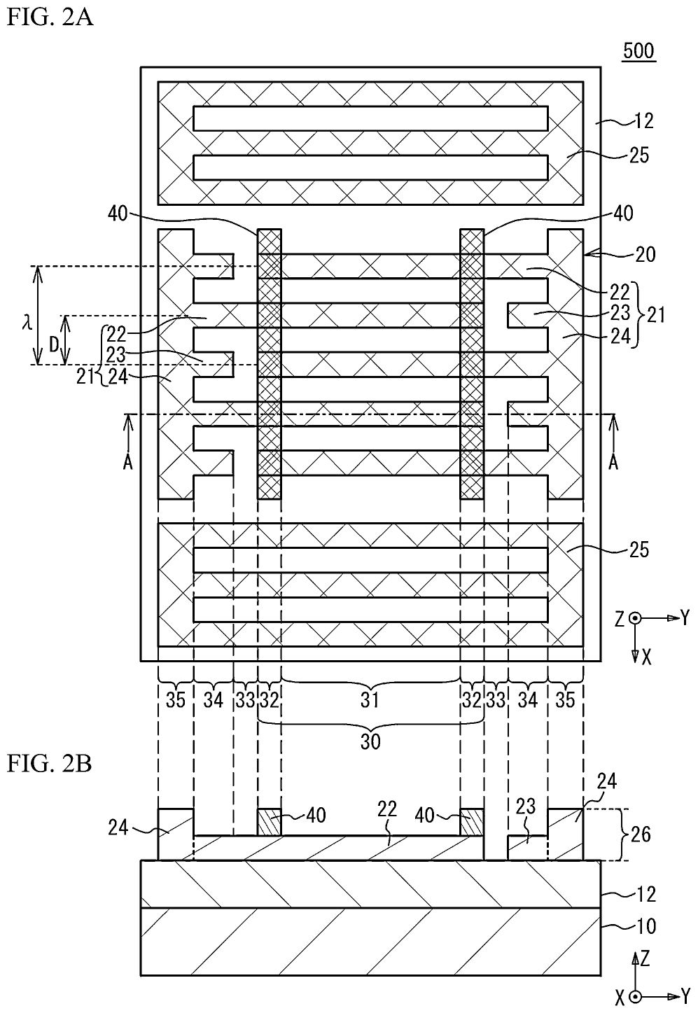

FIG. 2A is a plan view of an acoustic wave device 500 according to a comparative example, and FIG. 2B is a cross-sectional view taken along line A-A in FIG. 2A. As illustrated in FIG. 2A and FIG. 2B, in the comparative example, one dummy electrode finger 23 of one comb-shaped electrode 21 faces the tip of the electrode finger 22 of the other comb-shaped electrode 21 and is located between the electrode fingers 22 adjacent to each other in the X direction of one comb-shaped electrode 21. The width of the dummy electrode finger 23 in the X direction is the same as the width of the electrode finger 22 in the X direction. Other configurations are the same as those of the first embodiment, and thus the description thereof will be omitted.

### Acoustic Velocity of Acoustic Wave

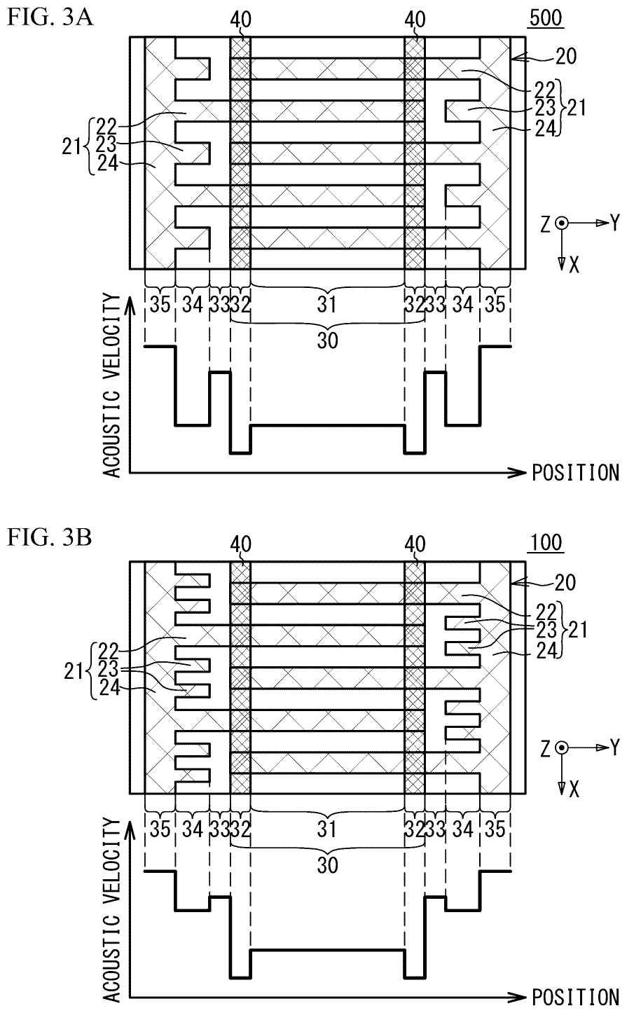

FIG. 3A illustrates the acoustic velocity of the acoustic wave in the comparative example, and FIG. 3B illustrates the acoustic velocity of the acoustic wave in the first embodiment. As illustrated in FIG. 3A, in the acoustic wave device 500 according to the comparative example, the dummy electrode fingers 23 have the same width and the same thickness as the electrode fingers 22. Therefore, the acoustic velocity of the acoustic wave propagating through the dummy region 34 is the same as the acoustic velocity of the acoustic wave propagating through the central region 31. Since the additional film 40 is provided in the edge region 32, the acoustic velocity of the acoustic wave propagating through the edge region 32 is lower than the acoustic velocity of the acoustic wave propagating through the central region 31. The piston mode can be achieved by adjusting the acoustic velocity of the acoustic wave propagating through the edge region 32 to be lower than the acoustic velocity of the acoustic wave propagating through the central region 31. The acoustic velocity of the acoustic wave propagating through the gap region 33 is higher than the acoustic velocity of the acoustic wave propagating through the central region 31 and the dummy region 34. The acoustic velocity of the acoustic wave is the acoustic velocity of the surface acoustic wave (for example, an SH wave) propagating on the surface of the piezoelectric substrate 12.

As illustrated in FIG. 3B, in the acoustic wave device 100 in accordance with the first embodiment, two dummy electrode fingers 23 having a smaller width than the electrode fingers 22 are provided between the electrode fingers 22 adjacent to each other in the X direction in one comb-shaped electrode 21. The provision of such dummy electrode fingers 23 causes the acoustic velocity of the acoustic wave propagating through the dummy region 34 to be higher than the acoustic velocity of the acoustic wave propagating through the central region 31. The acoustic velocity of the acoustic wave propagating through the dummy region 34 is, for example, equal to or less than 1.10 times the acoustic velocity of the acoustic wave propagating through the central region 31. Other configurations are the same as those in FIG. 3A, and thus the description thereof will be omitted.

The acoustic velocity of the acoustic wave can be obtained by, for example, the equation (1). In the equation (1), V represents the acoustic velocity, p represents the density, E represents Young's modulus, and v represents Poisson's ratio.

$$V = \sqrt{\frac{E}{ρ \times 2 \times ( 1 + v )}} \qquad ( 1 )$$

To achieve the piston mode, the length of the central region 31 in the Y direction and the length of the edge region 32 in the Y direction preferably satisfy a certain relationship. For example, the length of the central region 31 in the Y direction is preferably longer than the total length of the edge regions 32 in the Y direction. The length of each of the edge regions 32 in the Y direction is preferably 1λ or less (e.g., equal to or less than 1/20 of the aperture length), and more preferably 0.5λ or less (e.g., equal to or less than 1/40 of the opening length). The length of each of the edge regions 32 in the Y direction is preferably 0.05λ or greater (e.g., equal to or greater than 1/400 of the aperture length), and more preferably 0.1λ or greater (e.g., equal to or greater than 1/200 of the aperture length). The edge region 32 may be provided only on one side of the central region 31. The length of the gap region 33 in the Y direction is preferably 2λ or less (for example, equal to or less than 1/10 of the aperture length), and more preferably 1λ or less (for example, equal to or less than 1/20 of the aperture length). The length of each of the gap regions 33 in the Y direction is preferably 0.1λ or greater (for example, equal to or greater than 1/200 of the aperture length), and more preferably 0.2λ or greater (for example, equal to or greater than 1/100 of the aperture length).

### Simulation 1

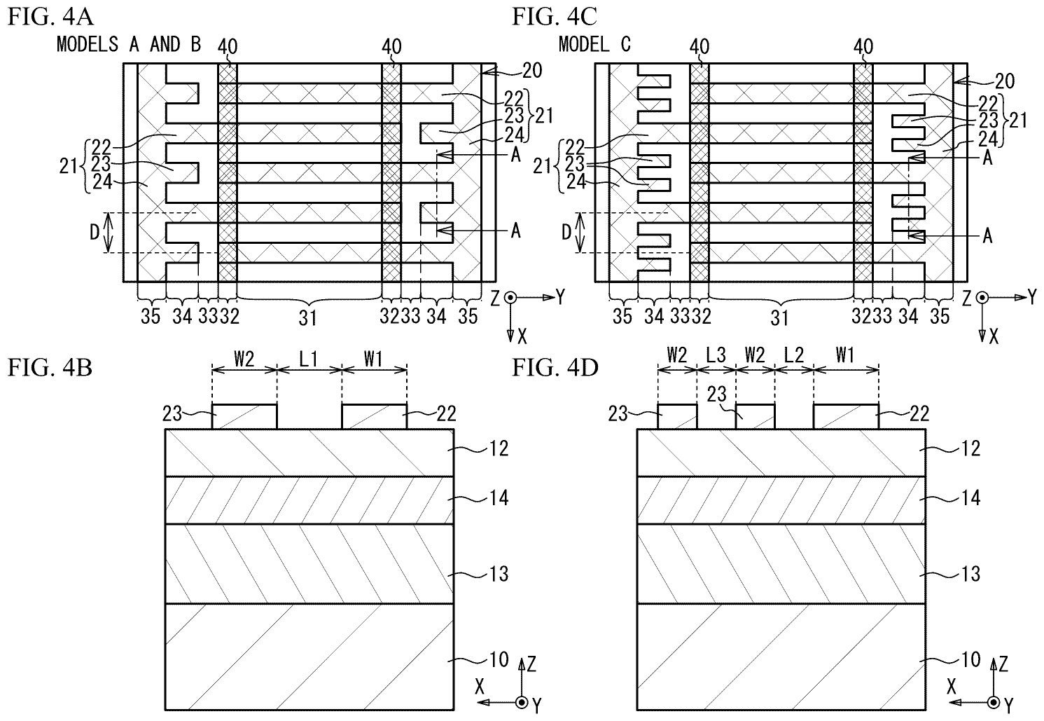

Simulation 1 regarding the higher acoustic velocity of the acoustic wave propagating through the dummy region 34 in the first embodiment will be described. FIG. 4A is a plan view of a model A and a model B on which Simulation 1 is performed, and FIG. 4B is a cross-sectional view taken along line A-A in FIG. 4A. FIG. 4C is a plan view of a model C on which Simulation 1 is performed, and FIG. 4D is a cross-sectional view taken along line A-A in FIG. 4C. Although the reflectors 25 sandwiching the IDT 20 therebetween are provided, they are not illustrated in FIG. 4A and FIG. 4C for the sake of clarity. As illustrated in FIG. 4B and FIG. 4D, in all of the models A, B, and C, the piezoelectric substrate 12 is bonded to the support substrate 10 with an insulating layer 13 and an insulating layer 14 interposed therebetween. As illustrated in FIG. 4A and FIG. 4C, the additional film 40 is provided in the edge region 32 in all of the models A, B, and C.

As illustrated in FIG. 4A, in the model A and the model B, one dummy electrode finger 23 is provided between the electrode fingers 22 adjacent to each other in the X direction in one comb-shaped electrode 21. In the model A, the width of the dummy electrode finger 23 is the same as the width of the electrode finger 22. In the model B, the width of the dummy electrode finger 23 is smaller than the width of the electrode finger 22. As illustrated in FIG. 4C, in the model C, two dummy electrode fingers 23 having a smaller width than the electrode finger 22 are provided between the electrode fingers 22 adjacent to each other in the X direction in one comb-shaped electrode 21.

The simulation conditions are as follows.

### Common Conditions for the Models a, B, and C

Wavelength λ of surface acoustic wave: 2.2 μm
Support substrate 10: Sapphire substrate
Insulating layer 13: Aluminum oxide layer with a thickness of 2.72λ
Insulating layer 14: Silicon oxide layer with a thickness of 0.2λ,
Piezoelectric substrate 12: 42° Y-cut X-propagation lithium tantalate substrate with a thickness of 0.3,
Electrode fingers 22, dummy electrode fingers 23, and bus bars 24: Aluminum film with a thickness of 0.07λ
Additional film 40: Niobium oxide film with a thickness of 0.01λ
Width W1 of the electrode finger 22: 0.55 μm
Pitch D of the electrode fingers 22: 1.1 μm

### Conditions for the Model A

Width W2 of the dummy electrode finger 23: 0.55 μm
Distance L1 between the electrode finger 22 and the dummy electrode finger 23: 0.55 μm

### Conditions for the Model B

Width W2 of the dummy electrode finger 23: 0.33 μm
Distance L1 between the electrode finger 22 and the dummy electrode finger 23: 0.66 μm

### Conditions for the Model C

Width W2 of the dummy electrode finger 23: 0.33 μm
Distance L2 between the electrode finger 22 and the dummy electrode finger 23 and distance L3 between the dummy electrode fingers 23: 0.33 μm

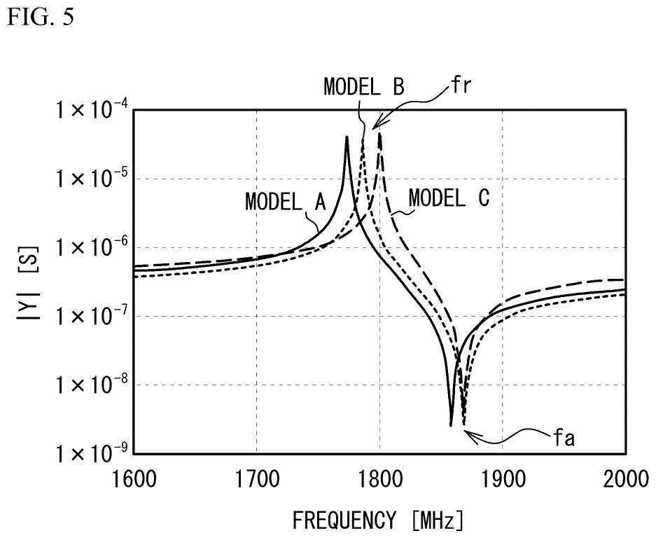

FIG. 5 is a graph illustrating the absolute value |Y| of admittance with respect to frequency in Simulation 1. In the absolute value |Y| of the admittance, peaks of the resonance frequency fr and the anti-resonance frequency fa are observed. As presented in FIG. 5, the resonance frequency fr of the model B is shifted to the higher frequency than that of the model A. In the model C, the resonance frequency fr is shifted to the higher frequency than in the model B. Compared to the case where the width W2 of the dummy electrode finger 23 is the same as the width W1 of the electrode finger 22 as in the model A, the acoustic velocity of the acoustic wave propagating through the dummy region 34 is increased by narrowing the width W2 of the dummy electrode finger 23 as in the model B. In such a case, the resonance frequency fr of the model B is shifted to the higher frequency than that of the model A. The resonance frequency fr of the model C is shifted to the higher frequency than that of the model B. This indicates that the acoustic velocity of the acoustic wave propagating through the dummy region is higher in the model C than in the model B. Therefore, in the first embodiment, as illustrated in FIG. 3B, the acoustic velocity of the acoustic wave propagating through the dummy region 34 is increased.

### Simulation 2

Simulation 2 was performed on the acoustic velocity and spurious emissions in the dummy region 34. Simulation 2 was performed using models D, E, F, G, and H having the structures illustrated in FIG. 4A and FIG. 4B. The simulation conditions are as follows.

### Common Conditions for the Models D, E, F, G, and H

Wavelength λ of surface acoustic wave: 5.0 μm
Support substrate 10: Sapphire substrate
Insulating layer 13: Aluminum oxide layer with a thickness of 2.72λ
Insulating layer 14: Silicon oxide layer with a thickness of 0.2λ
Piezoelectric substrate 12: 42° Y-cut X-propagation lithium tantalate substrate with a thickness of 0.3λ
Electrode fingers 22, dummy electrode fingers 23, and bus bars 24: Aluminum film with a thickness of 0.1λ
Additional film 40: Niobium oxide film with a thickness of 0.01λ
Width W1 of the electrode finger 22: 1.25 μm
Pitch D of the electrode fingers 22: 2.5 μm
Acoustic velocity in the central region 31: 3750 m/s
Acoustic velocity in the edge region 32: 3675 m/s
Acoustic velocity in the gap region 33: 4200 m/s

### Conditions for the Model D

Acoustic velocity in the dummy region 34: the same as the acoustic velocity in the central region 31 (3750 m/s)

### Conditions for the Model E

Acoustic velocity in the dummy region 34: 1.03 times the acoustic velocity in the central region 31 (3862.5 m/s)

### Conditions for the Model F

Acoustic velocity in the dummy region 34: 1.05 times the acoustic velocity in the central region 31 (3937.5 m/s)
   Conditions for the model G
Acoustic velocity in the dummy region 34: 1.08 times the acoustic velocity in the central region 31 (4050 m/s)

### Conditions for the Model H

Acoustic velocity in the dummy region 34: 1.10 times the acoustic velocity in the central region 31 (4125 m/s)

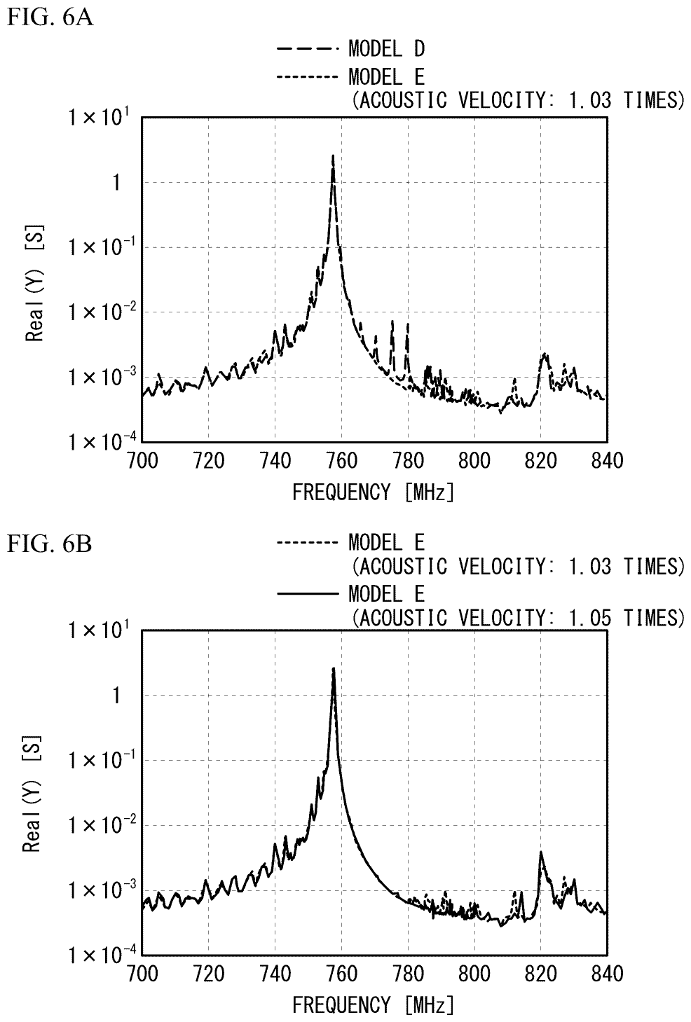

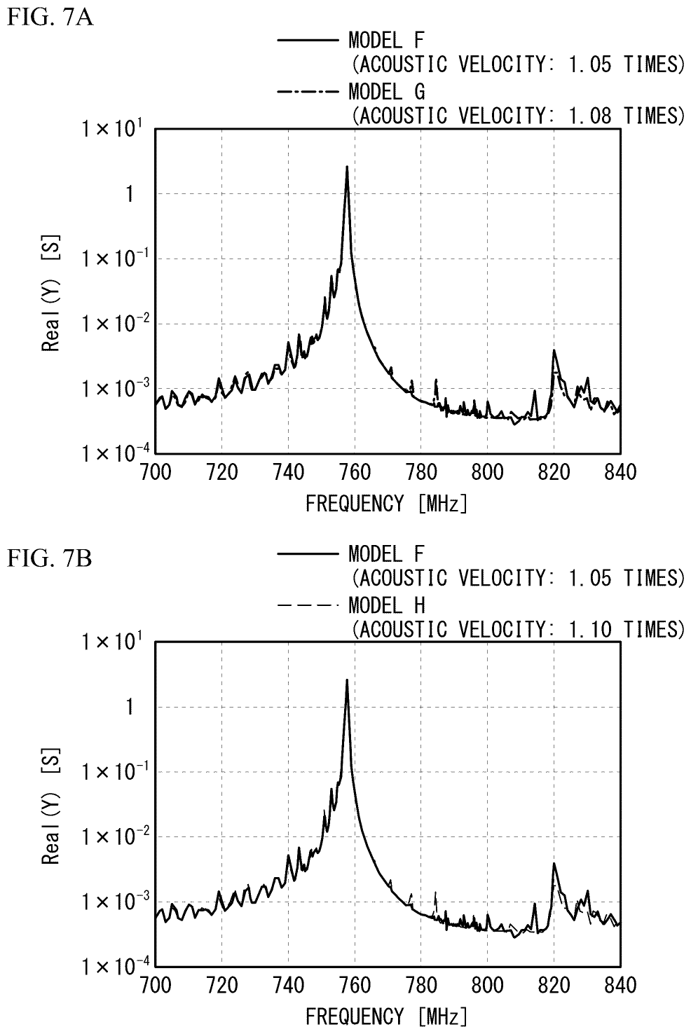

FIG. 6A to FIG. 7B are graphs presenting the real part Real (Y) of admittance with respect to frequency in Simulation 2. In the real part Real (Y) of the admittance, a larger spurious response is observed than in the absolute value Y. As presented in FIG. 6A, spurious emissions were reduced in the model E as compared with the model D. As presented in FIG. 6B, spurious emissions were reduced in the model F as compared with the model E. As presented in FIG. 7A and FIG. 7B, the spurious emission at around 780 MHz is larger in the models G and H than in the model F, but the spurious emission is smaller in the models G and H than in the model D.

The results of Simulation 2 reveal that spurious emissions can be reduced by adjusting the acoustic velocity of the acoustic wave in the dummy region 34 to be higher than the acoustic velocity of the acoustic wave in the central region 31, as in the models E to H. In addition, since the spurious emission is larger in the models G and H than in the model F, it is found that there is an upper limit in the acoustic velocity of the acoustic wave in the dummy region 34. To reduce spurious emissions, the acoustic velocity of the acoustic wave in the dummy region 34 is preferably equal to or less than 1.10 times, more preferably equal to or less than 1.08 times, and further preferably equal to or less than 1.06 times the acoustic velocity of the acoustic wave in the central region 31, for example.

When the displacement of the standing wave generated in the Y direction in the IDT 20 is completely canceled out in the positive and negative directions, no spurious emission is generated, but the portion that cannot be canceled out appears as the spurious emission. When the acoustic velocity of the acoustic wave in the dummy region 34 becomes higher than the acoustic velocity of the acoustic wave in the central region 31, the shape of the standing wave changes due to the enhanced confinement effect. It is considered that the change in the shape of the standing wave reduces the displacement of the standing wave that cannot be canceled between positive and negative directions, and as a result, the spurious emission is reduced in the models E to H.

### First Variation

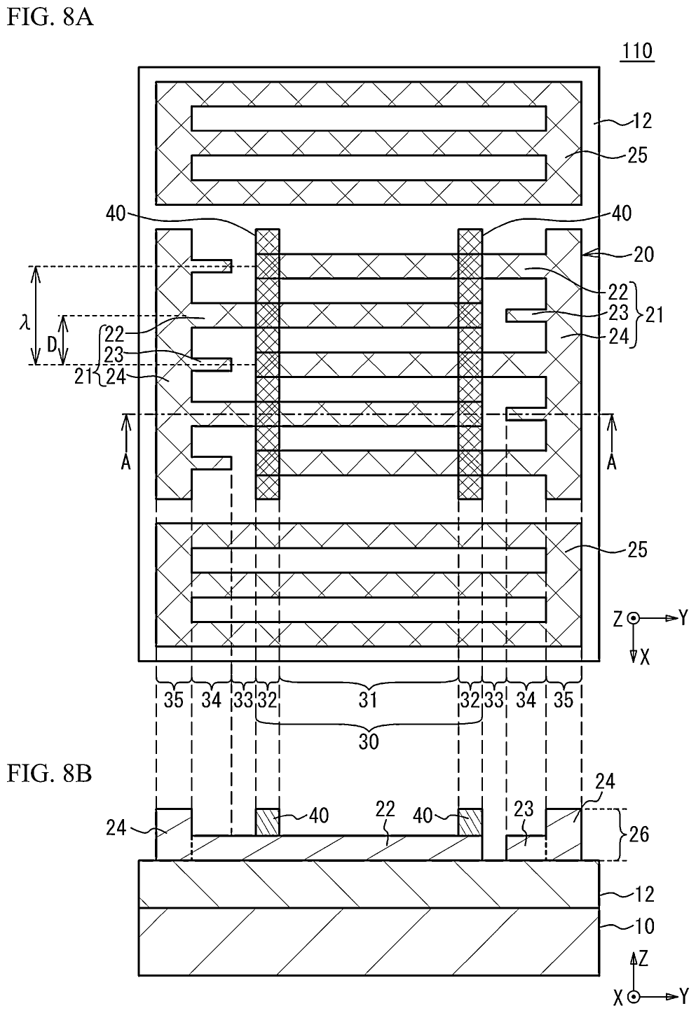

FIG. 8A is a plan view of an acoustic wave device 110 in accordance with a first variation of the first embodiment, and FIG. 8B is a cross-sectional view taken along line A-A in FIG. 8A. As illustrated in FIG. 8A and FIG. 8B, in the first variation of the first embodiment, one dummy electrode finger 23 is provided between the electrode fingers 22 adjacent to each other in the X direction in one comb-shaped electrode 21. The tips of the dummy electrode fingers 23 of one of the comb-shaped electrodes 21 face the tips of the electrode fingers 22 of the other comb-shaped electrode 21, respectively. The width of the dummy electrode finger 23 in the X direction is smaller than the width of the electrode finger 22 in the X direction. Other configurations are the same as those of the first embodiment, and thus the description thereof will be omitted. In the first variation of the first embodiment, the acoustic velocity of the acoustic wave in the dummy region 34 is higher than the acoustic velocity of the acoustic wave in the central region 31. The acoustic velocity of the acoustic wave propagating through the dummy region 34 is, for example, equal to or less than 1.10 times the acoustic velocity of the acoustic wave propagating through the central region 31.

### Experiment

The acoustic wave devices according to the first embodiment and the first variation of the first embodiment were fabricated and an experiment for evaluating spurious emissions was conducted. The experimental conditions are as follows.

### Common Conditions

Wavelength λ of the surface acoustic wave: 3 μm
Support substrate 10: Sapphire substrate
Piezoelectric substrate 12: 42° Y-cut X-propagation lithium tantalate substrate with a thickness of 0.15λ
Electrode fingers 22, dummy electrode fingers 23, and bus bars 24: Aluminum film with a thickness of 0.03λ
Additional film 40: Niobium oxide film with a thickness of 0.007λ
Width of the electrode finger 22: 0.76 μm
Duty ratio of the electrode finger 22: 50%

### Conditions for the First Embodiment

Width of the dummy electrode finger 23: 0.5 μm
Duty ratio of the dummy electrode finger 23: 50%
Acoustic velocity in the dummy region 34: 1.05 times the acoustic velocity in the central region 31

### Conditions for the First Variation of the First Embodiment

Width of the dummy electrode finger 23: 0.5 μm
Duty ratio of the dummy electrode finger 23: 30%
Acoustic velocity in the dummy region 34: 1.03 times the acoustic velocity in the central region 31

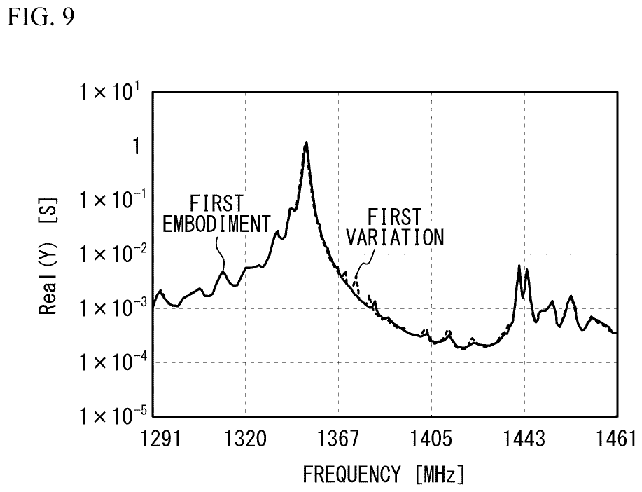

FIG. 9 presents experimental results of the real part Real(Y) of the admittance with respect to the frequency in the first embodiment and the first variation of the first embodiment. As presented in FIG. 9, the experimental result of the first embodiment in which the acoustic velocity in the dummy region 34 is 1.05 times the acoustic velocity in the central region 31 and the experimental result of the first variation of the first embodiment in which the acoustic velocity in the dummy region 34 is 1.03 times the acoustic velocity in the central region 31 are similar to the simulation result of the model F in which the acoustic velocity in the dummy region 34 is 1.05 times the acoustic velocity in the central region 31 and the simulation result of the model E in which the acoustic velocity in the dummy region 34 is 1.03 times the acoustic velocity in the central region 31 presented in FIG. 6B, respectively.

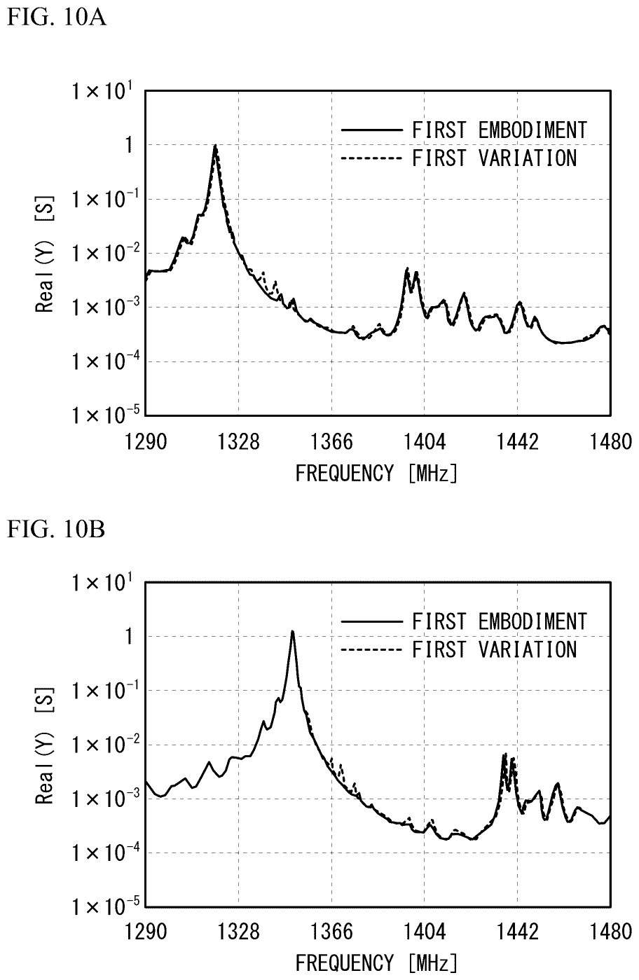

FIG. 10A and FIG. 10B present experimental results of the real part Real(Y) of the admittance with respect to the frequency in the case where the stacking structure of the substrate is changed in the first embodiment and the first variation of the first embodiment. FIG. 10B presents the experimental results when a high acoustic velocity film with a thickness of 0.25λ is provided between the support substrate 10 and the piezoelectric substrate 12 in addition to the structure illustrated in FIG. 10A. As presented in FIG. 10A and FIG. 10B, even when the stacking structure of the substrate was different, the similar results to those of FIG. 9 were obtained. This indicates that the influence of the stacking structure of the substrate is small.

### Second and Third Variations

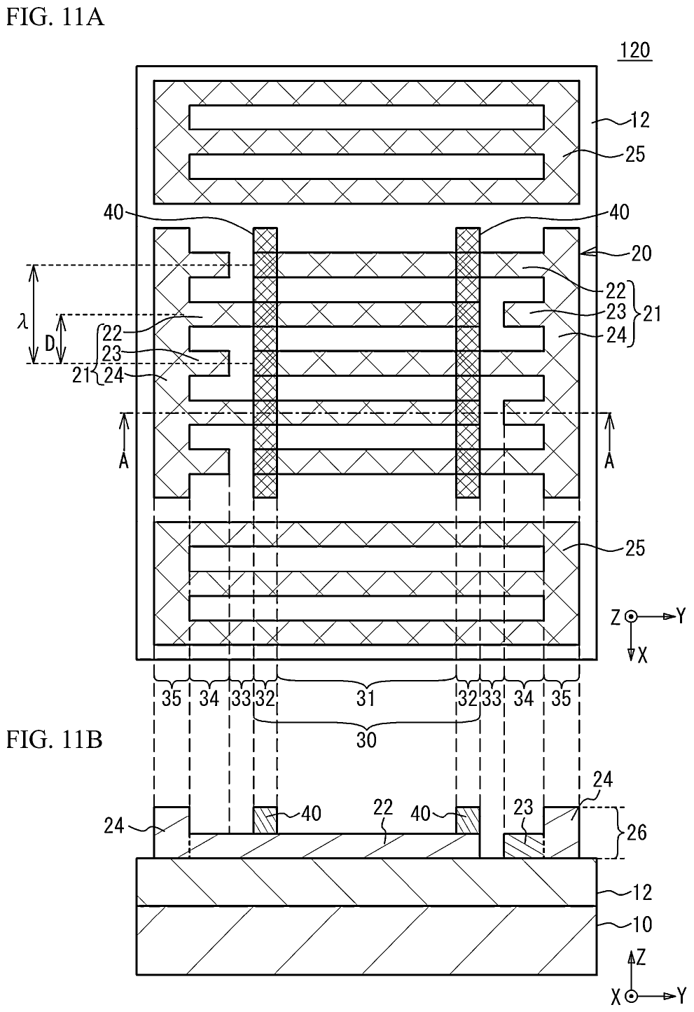

FIG. 11A is a plan view of an acoustic wave device 120 in accordance with a second variation of the first embodiment, and FIG. 11B is a cross-sectional view taken along line A-A in FIG. 11A. As illustrated in FIG. 11A and FIG. 11B, in the second variation of the first embodiment, one dummy electrode finger 23 having the same width as the electrode finger 22 is provided between the electrode fingers 22 adjacent to each other in the X direction in one comb-shaped electrode 21. The dummy electrode fingers 23 face the tips of the electrode fingers 22 of the other comb-shaped electrode 21, respectively, and are formed mainly of a material having a higher acoustic velocity than the electrode fingers 22. For example, when the electrode fingers 22 are formed of aluminum as a main component, the dummy electrode fingers 23 are formed of beryllium or sodium as a main component. When the electrode fingers 22 are formed of gold, molybdenum, or tungsten as a main component, the dummy electrode fingers 23 are formed of aluminum as a main component. To compare the acoustic velocities here, the acoustic velocities obtained from the above equation (1) may be compared. Other configurations are the same as those of the first embodiment, and thus the description thereof will be omitted. In the second variation of the first embodiment, the acoustic velocity of the acoustic wave in the dummy region 34 is higher than the acoustic velocity of the acoustic wave in the central region 31. The acoustic velocity of the acoustic wave propagating through the dummy region 34 is, for example, equal to or less than 1.10 times the acoustic velocity of the acoustic wave propagating through the central region 31.

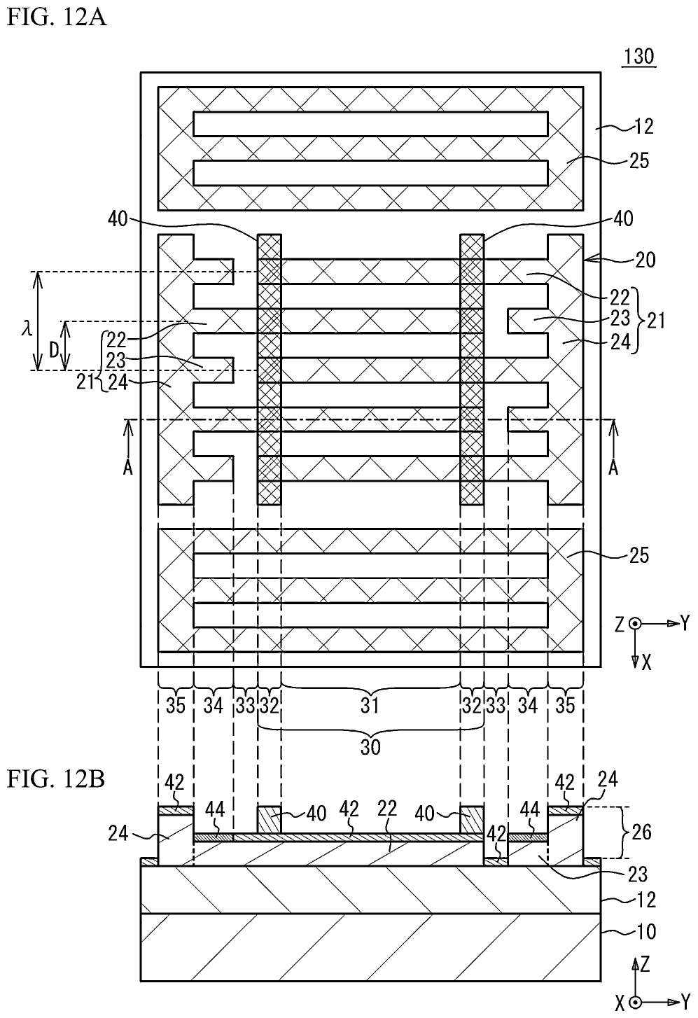

FIG. 12A is a plan view of an acoustic wave device 130 in accordance with a third variation of the first embodiment, and FIG. 12B is a cross-sectional view taken along line A-A in FIG. 12A. As illustrated in FIG. 12A and FIG. 12B, in the third variation of the first embodiment, one dummy electrode finger 23 having the same width as the electrode finger 22 is provided between the electrode fingers 22 adjacent to each other in the X direction in one comb-shaped electrode 21. The dummy electrode fingers 23 face the tips of the electrode fingers 22 of the other comb-shaped electrode 21 and are formed of the same material as the electrode fingers 22 as a main component. A protective film 42 is provided on the piezoelectric substrate 12 in the overlap region 30, the gap region 33, and the bus bar region 35 so as to cover the electrode fingers 22 and the bus bars 24. A protective film 44, which is mainly composed of a material having a higher acoustic velocity than the protective film 42, is provided on the piezoelectric substrate 12 in the dummy region 34 so as to cover the dummy electrode fingers 23. For example, when the protective film 42 is formed of silicon oxide as a main component, the protective film 44 is formed of silicon nitride as a main component. The protective film 42 and the protective film 44 have the same thickness. The acoustic velocities may be compared by comparing the acoustic velocities obtained from the above equation (1). Other configurations are the same as those of the first embodiment, and thus the description thereof will be omitted. In the third variation of the first embodiment, the acoustic velocity of the acoustic wave in the dummy region 34 is higher than the acoustic velocity of the acoustic wave in the central region 31. The acoustic velocity of the acoustic wave propagating through the dummy region 34 is, for example, equal to or less than 1.10 times the acoustic velocity of the acoustic wave propagating through the central region 31.

As described above, in the first embodiment and the variations thereof, the acoustic velocity of the acoustic wave propagating through the dummy region 34 is higher than the acoustic velocity of the acoustic wave propagating through the central region 31 and is equal to or less than 1.10 times the acoustic velocity of the acoustic wave propagating through the central region 31. Thus, as illustrated in FIG. 6A to FIG. 7B, spurious emissions can be reduced. To reduce spurious emissions, the acoustic velocity of the acoustic wave propagating through the dummy region 34 is preferably equal to or less than 1.09 times, more preferably equal to or less than 1.08 times, and further preferably equal to or less than 1.07 times the acoustic velocity of the acoustic wave propagating through the central region 31, for example.

In the first embodiment and the variations thereof, the acoustic velocity of the acoustic wave propagating through the dummy region 34 is equal to or greater than 1.03 times the acoustic velocity of the acoustic wave propagating through the central region 31. Thus, as illustrated in FIG. 6A to FIG. 7A, spurious emissions can be reduced. To reduce spurious emissions, the acoustic velocity of the acoustic wave propagating through the dummy region 34 is preferably equal to or greater than 1.04 times, and more preferably equal to or greater than 1.05 times the acoustic velocity of the acoustic wave propagating through the central region 31, for example.

In the first embodiment, as illustrated in FIG. 1A, two dummy electrode fingers 23 are provided between the electrode fingers 22 adjacent to each other in the X direction of the electrode fingers 22 in one comb-shaped electrode 21. The width of the dummy electrode finger 23 in the X direction is smaller than the width of the electrode finger 22 in the X direction. The provision of such dummy electrode fingers 23 increases the acoustic velocity of the acoustic wave propagating through the dummy region 34 to be higher than the acoustic velocity of the acoustic wave propagating through the central region 31. Thus, spurious emissions can be reduced.

When two dummy electrode fingers 23 are provided between the electrode fingers 22 adjacent to each other in the X direction, the width of the dummy electrode finger 23 in the short direction (X direction) may be equal to or greater than 0.56 times and equal to or less than 0.64 times the width of the electrode finger 22 in the short direction (X direction). In this case, the duty ratio of the electrode finger 22 and the duty ratio of the dummy electrode finger 23 can be set within a range of 30% to 70% to improve the ease of manufacturing. The acoustic velocity of the acoustic wave in the dummy region 34 is equal to or greater than 1.03 times and equal to or less than 1.10 times the acoustic velocity of the acoustic wave in the central region 31. The widths of the dummy electrode fingers 23 in the short direction are preferably equal to each other. Equal width means that a difference of manufacturing error is acceptable, e.g., a ratio of two widths of 0.95 or greater and 1.05 or less is acceptable.

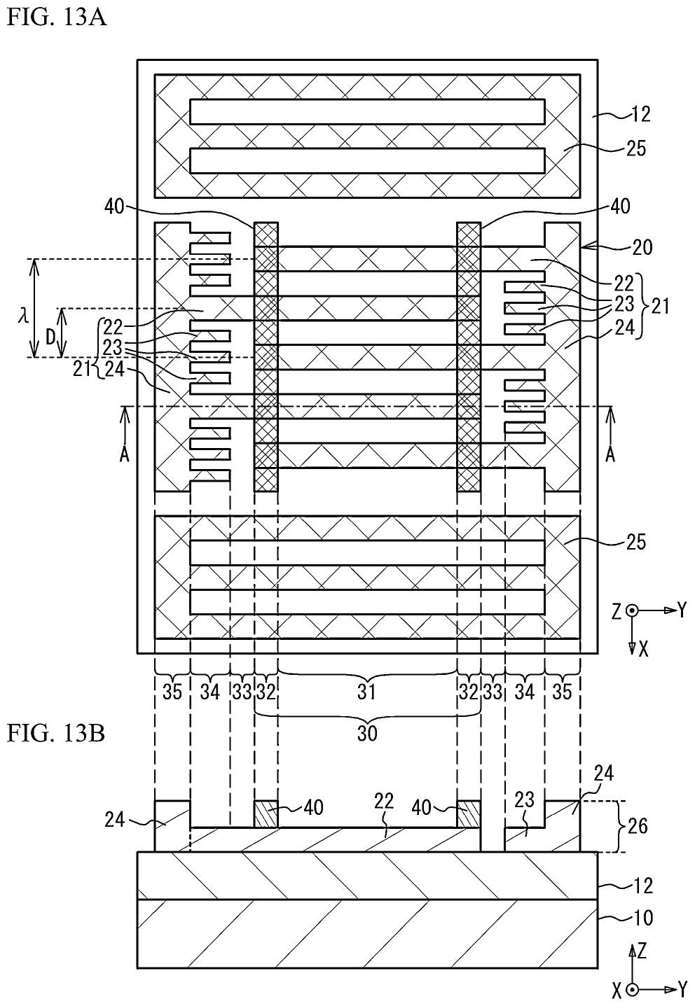

FIG. 13A is a plan view of the case where three dummy electrode fingers 23 are provided between the adjacent electrode fingers 22 in the first embodiment, and FIG. 13B is a cross-sectional view taken along line A-A in FIG. 13A. As illustrated in FIG. 13A and FIG. 13B, three dummy electrode fingers 23 may be provided between the electrode fingers 22 adjacent to each other in the X direction. In this case, the width of the dummy electrode finger 23 in the short direction (X direction) may be equal to or greater than 0.39 times and equal to or less than 0.45 times the width of the electrode finger 22 in the short direction (X direction). In this case, the duty ratio of the electrode finger 22 and the duty ratio of the dummy electrode finger 23 can be set within a range of 30% to 70% to improve the ease of manufacturing. The acoustic velocity of the acoustic wave in the dummy region 34 is equal to or greater than 1.03 times and equal to or less than 1.10 times the acoustic velocity of the acoustic wave in the central region 31. The widths of the dummy electrode fingers 23 in the short direction are preferably equal to each other.

The number of the dummy electrode fingers 23 provided between the electrode fingers 22 adjacent to each other in the X direction is not limited to two or three, and is to be two or more.

In the first variation of the first embodiment, as illustrated in FIG. 8A, the dummy electrode fingers 23 of one of the comb-shaped electrodes 21 face the electrode fingers 22 of the other of the comb-shaped electrodes 21, and the width of the dummy electrode finger 23 in the short direction (X direction) is smaller than the width of the electrode finger 22 in the short direction (X direction). As a result, the acoustic velocity of the acoustic wave propagating through the dummy region 34 is higher than the acoustic velocity of the acoustic wave propagating through the central region 31. Thus, spurious emissions can be reduced.

In the second variation of the first embodiment, as illustrated in FIG. 11A and FIG. 11B, the dummy electrode fingers 23 are mainly composed of a material having a higher acoustic velocity of the acoustic wave than the electrode fingers 22. Therefore, the acoustic velocity of the acoustic wave propagating through the dummy region 34 is higher than the acoustic velocity of the acoustic wave propagating through the central region 31. Thus, spurious emissions can be reduced.

In the third variation of the first embodiment, as illustrated in FIG. 12B, the protective film 42 (first insulating film) is provided on the piezoelectric substrate 12 to cover the electrode fingers 22 in the central region 31. The protective film 44 (second insulating film) that contains, as a main component, a material having a higher acoustic velocity of an acoustic wave than the protective film 42 is provided on the piezoelectric substrate 12 so as to cover the dummy electrode fingers 23 in the dummy region 34. Therefore, the acoustic velocity of the acoustic wave propagating through the dummy region 34 is higher than the acoustic velocity of the acoustic wave propagating through the central region 31. Thus, spurious emissions can be reduced.

As a method for making the acoustic velocity of the acoustic wave propagating through the dummy region 34 higher than the acoustic velocity of the acoustic wave propagating through the central region 31, a method other than the above-described methods may be used. For example, the thickness of the dummy electrode finger 23 may be smaller than that of the electrode finger 22. For example, the thickness of the piezoelectric substrate 12 in the dummy region 34 can be made to be smaller than that of the piezoelectric substrate 12 in the central region 31. For example, a material having a higher acoustic velocity of an acoustic wave than the piezoelectric substrate 12 can be provided in the dummy region 34.

### Second Embodiment

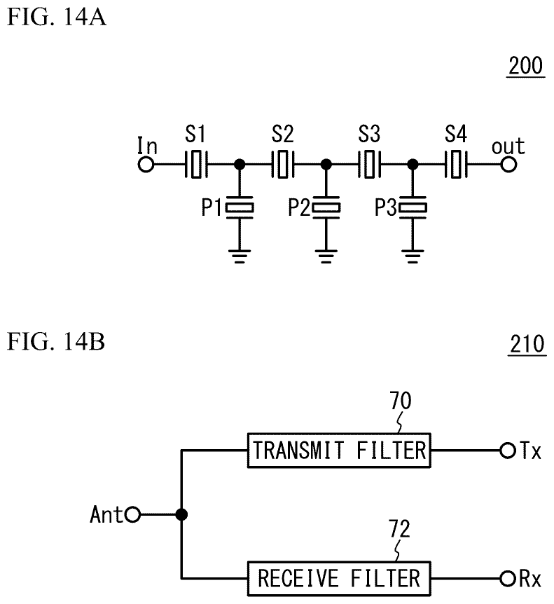

In the first embodiment, the acoustic wave device is an acoustic wave resonator. In a second embodiment and the variation of the second embodiment, cases where the acoustic wave device is a filter and a duplexer will be described. FIG. 14A is a circuit diagram of a filter 200 in accordance with the second embodiment. As illustrated in FIG. 14A, one or more series resonators S1 to S4 are connected in series between an input terminal Tin and an output terminal Tout. One or more parallel resonators P1 to P3 are connected in parallel between the input terminal Tin and the output terminal Tout. The acoustic wave resonator of the first embodiment or the variations thereof may be used for at least one of the following resonators: the series resonators S1 to S4 and the parallel resonators P1 to P3. The number of series resonators and parallel resonators can be set as appropriate. Although the ladder-type filter is described as an example of the filter, the filter may be a multimode filter.

FIG. 14B is a circuit diagram of a duplexer 210 in accordance with a variation of the second embodiment. As illustrated in FIG. 14B, a transmit filter 70 is connected between a common terminal Ant and a transmit terminal Tx. A receive filter 72 is connected between the common terminal Ant and a receive terminal Rx. The transmit filter 70 transmits signals in the transmit band to the common terminal Ant as transmission signals among high-frequency signals input from the transmit terminal Tx, and suppresses signals with other frequencies. The receive filter 72 transmits signals in the receive band to the receive terminal Rx as reception signals among high-frequency signals input from the common terminal Ant, and suppresses signals with other frequencies. One of or both of the transmit filter 70 and the receive filter 72 may be the filter of the second embodiment. Although the duplexer is exemplified as the multiplexer, the multiplexer may be a triplexer or a quadplexer.

Although the embodiment of the present invention has been described in detail above, the present invention is not limited to the specific embodiment, and various modifications and changes can be made within the scope of the gist of the present invention described in the claims.

What is claimed is:

1. An acoustic wave device comprising:
a piezoelectric substrate; and
a pair of comb-shaped electrodes provided on the piezoelectric substrate, each of the pair of comb-shaped electrodes including a plurality of electrode fingers and a plurality of metal portions, the plurality of metal portions being provided between electrode fingers adjacent to each other in a short direction of the plurality of electrode fingers, the plurality of metal portions having a shorter length in a long direction than the plurality of electrode fingers, the plurality of electrode fingers of one of the pair of comb-shaped electrodes and the plurality of electrode fingers of the other of the pair of comb-shaped electrodes being alternately arranged at least in a part, an acoustic velocity of an acoustic wave propagating through a region where the plurality of metal portions are located being higher than an acoustic velocity of an acoustic wave propagating through a central region of an overlap region where the plurality of electrode fingers of the one of the pair of comb-shaped electrodes and the plurality of electrode fingers of the other of the pair of comb-shaped electrodes overlap, and being equal to or less than 1.10 times the acoustic velocity of the acoustic wave propagating through the central region.

2. The acoustic wave device according to claim 1, wherein the acoustic velocity of the acoustic wave propagating through the region where the plurality of metal portions are located is equal to or greater than 1.03 times the acoustic velocity of the acoustic wave propagating through the central region.

3. The acoustic wave device according to claim 1,
wherein the plurality of metal portions of the one of the pair of comb-shaped electrodes face the plurality of electrode fingers of the other of the pair of comb-shaped electrodes, and
wherein the widths of the plurality of metal portions in the short direction are smaller than the widths of the plurality of electrode fingers in the short direction.

4. The acoustic wave device according to claim 1, further comprising:
a first insulating film provided on the piezoelectric substrate so as to cover the plurality of electrode fingers in the central region; and
a second insulating film provided on the piezoelectric substrate to cover the plurality of metal portions in the region where the plurality of metal portions are located, the second insulating film containing, as a main component, a material having a higher acoustic velocity of an acoustic wave than the first insulating film.

5. The acoustic wave device according to claim 1, further comprising an additional film provided at an end portion of each of the plurality of electrode fingers in the long direction.

6. An acoustic wave device comprising:
a piezoelectric substrate; and
a pair of comb-shaped electrodes provided on the piezoelectric substrate, each of the pair of comb-shaped electrodes including a plurality of electrode fingers and a plurality of metal portions, two or more of the plurality of metal portions being provided between adjacent electrode fingers in a short direction of the plurality of electrode fingers, the plurality of metal portions having a smaller width in the short direction than the plurality of electrode fingers, the plurality of electrode fingers of one of the pair of comb-shaped electrode fingers and the plurality of electrode fingers of the other of the pair of comb-shaped electrode fingers being alternately arranged at least in a part.

7. The acoustic wave device according to claim 6,
wherein two of the plurality of metal portions are provided between the adjacent electrode fingers, and
wherein widths of the plurality of metal portions in the short direction are equal to or greater than 0.56 times and equal to or less than 0.64 times widths of the plurality of electrode fingers in the short direction.

8. The acoustic wave device according to claim 6,
wherein three of the plurality of metal portions are provided between the adjacent electrode fingers, and
wherein widths of the plurality of metal portions in the short direction are equal to or greater than 0.39 times and equal to or less than 0.45 times widths of the plurality of electrode fingers in the short direction.

9. The acoustic wave device according to claim 7,
wherein the widths of the plurality of electrode fingers in the short direction are equal from one end connected to a bus bar to the other end on an opposite side, and
wherein the widths of the plurality of metal portions in the short direction are equal to each other.

10. An acoustic wave device comprising:
a piezoelectric substrate; and
a pair of comb-shaped electrodes provided on the piezoelectric substrate, each of the pair of comb-shaped electrodes including a plurality of electrode fingers and a plurality of metal portions, the plurality of metal portions being provided between adjacent electrode fingers of the plurality of electrode fingers in a short direction of the plurality of electrode fingers, the plurality of metal portions containing a material having a higher acoustic velocity of an acoustic wave than the plurality of electrode fingers as a main component, the plurality of electrode fingers of one of the pair of comb-shaped electrodes and the plurality of electrode fingers of the other of the pair of comb-shaped electrodes being alternately arranged at least in a part.
